(19) United States
(12) Patent Application Publication
(10) Pub. No.: US 2008/0180135 A1
(43) Pub. Date: Jul. 31, 2008

(54) Hysteresis circuit applied to comparator and amplifier circuit thereof

(75) Inventor: Cheng-Shun Fan, Taipei (TW)

Correspondence Address: RABIN & Berdo, PC, 1101 14TH STREET, NW, SUITE 500, WASHINGTON, DC, 20005, US

(73) Assignee: INVENTEC CORPORATION, Taipei (TW)

(21) Appl. No.: 11/698,889

(22) Filed: Jan. 29, 2007

(51) Int. Cl. H03K 5/24; H03F 3/45

(52) U.S. Cl. 327/89; 327/205; 330/260

(57) ABSTRACT

A hysteresis circuit applied to a comparator and an amplifier circuit thereof are provided. A hysteresis circuit is disposed on a positive feedback path of the comparator, such that the comparator resists noise interferences, and the hysteresis circuit has a feature of not affecting the feedback voltage signal, thereby making the hysteresis range of the comparator be more precise.

### BACKGROUND OF THE INVENTION

1. Field of Invention

The present invention relates to a hysteresis circuit. More particularly, the present invention relates to a hysteresis circuit applied to a comparator and an amplifier circuit thereof.

2. Related Art

In order to solve output misdeterminations of comparator circuits caused by noise interferences, usually a common method is using an internal circuit of a comparator and a positive feedback mechanism to generate the hysteresis, so as to achieve the function of noise resistance. Referring to FIG. 1, a schematic view of the signal converting of a common hysteresis circuit is shown, wherein a horizontal axis indicates an input voltage signal Vin, and a vertical axis indicates an output voltage signal Vout. When the output voltage signal Vout is a low level voltage Vol, the input voltage signal Vin must be raised till it is higher than an upper limit threshold voltage value Vth, the output voltage signal Vout is converted from the low level voltage Vol to a high level voltage Voh.

When the output voltage signal Vout is the high level voltage Voh, the input voltage signal Vin must be lowered till it is lower than a lower limit threshold voltage value Vtl, the output voltage signal Vout is converted from the high level voltage Voh to the low level voltage Vol. Therefore, when the input voltage signal Vin of the comparator has the noise interference, through the hysteresis generated by the hysteresis circuit, the comparator does not tend to be interfered by the noise to generate misoperation.

Next, referring to FIG. 2A, a schematic view of a common hysteresis circuit is shown. Mainly, a hysteresis circuit 10 is disposed on a positive feedback path of a comparator 20, such that the comparator 20 resists the noise interference, wherein a reference voltage signal Vref of the input comparator 20 is generated by a power source voltage regulator 30, and the hysteresis circuit 10 is formed by a resistor R1. Although the hysteresis circuit 10 has the advantages of low cost and simple architecture, because the resistor R1 is disposed, the input voltage signal Vin of the comparator 20 is affected by the resistor R1, a resistor R2, and a resistor R3, such that the precision of the hysteresis range of the comparator 20 is reduced.

Therefore, another hysteresis circuit designing manner is generated, referring to FIG. 2B, a schematic view of another hysteresis circuit is shown. It is designed mainly for the hysteresis circuit 11, and the hysteresis circuit 11 is formed by the resistor R1 and a diode D. In this manner, although the input voltage signal Vin of the comparator 20 is not affected by the resistor R1, because the diode D has a forward voltage drop, the precision of the hysteresis range of the comparator 20 is also reduced.

Therefore, when the comparator adopts a common hysteresis circuit design, because of the features of the circuit elements in the hysteresis circuit, the hysteresis range of the comparator is affected and is not precise.

### SUMMARY OF THE INVENTION

In view of the above problems, the object of the present invention is to provide a hysteresis circuit applied to a comparator and an amplifier circuit thereof, such that the threshold comparison voltage of the comparator is not affected by the hysteresis circuit, thereby making the hysteresis range of the comparator be more precise.

In the hysteresis circuit applied to the comparator disclosed according to the present invention, the comparator has a first input end, a second input end, and an output end. The first input end receives an input voltage signal, and the second input end receives a reference voltage signal. The comparator outputs a high level voltage signal or a low level voltage signal from the output end according to a difference between the input voltage signal and the reference voltage signal. The hysteresis circuit comprises a first resistor, a diode, and an operational amplifier.

The first resistor is electrically coupled between the first input end and the output end of the comparator. The diode is electrically coupled to the first resistor. The operational amplifier has a first input end, a second input end, and an output end, and is electrically coupled between the diode and the output end of the comparator. The first input end of the operational amplifier receives the high level voltage signal or the low level voltage signal, and the output end of the operational amplifier outputs the high level voltage signal or the low level voltage signal, so as to increase the difference between the input voltage signal and the reference voltage signal of the comparator.

The amplifier circuit disclosed according to the present invention comprises a first operational amplifier and a hysteresis circuit.

The first operational amplifier has a first OP input end, a second OP input end, and an OP output end. The first OP input end receives an input voltage signal, and the second OP input end receives a reference voltage signal. The first operational amplifier outputs a high level voltage signal or a low level voltage signal from the OP output end according to a difference between the input voltage signal and the reference voltage signal.

The hysteresis circuit is electrically coupled between the first input end and the output end of the first operational amplifier, wherein the hysteresis circuit comprises a first resistor, a diode, and a second operational amplifier.

The first resistor is electrically coupled between the first input end and the output end of the first operational amplifier. The diode is electrically coupled to the first resistor. The second operational amplifier has a first input end, a second input end, and an output end, and is electrically coupled between the diode and the output end of the first operational amplifier. The first input end of the second operational amplifier receives the high level voltage signal or the low level voltage signal, and the output end of the second operational amplifier outputs the high level voltage signal or low level voltage signal, so as to increase the difference between the input voltage signal and the reference voltage signal of the first operational amplifier.

By using the hysteresis circuit applied to the comparator and the amplifier circuit thereof, and using the feature that the operational amplifier and the diode forms a super diode circuit, the diode forward voltage drop in the former hysteresis circuit is nearly zero. In this manner, a feedback voltage signal of the comparator is not affected by the hysteresis circuit, thereby improving the precision of the hysteresis range of the comparator. Compared with the conventional hysteresis circuit design, the hysteresis circuit architecture of the present invention is achieved by only disposing an operational amplifier, and thus it has a simple circuit architecture.

The features and practices of the present invention are illustrated in detail below through the preferred embodiments with the accompanying drawings.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, and thus is not limitative of the present invention, and wherein:

FIG. 1 is a schematic view of the signal converting of a hysteresis circuit according to the prior art;

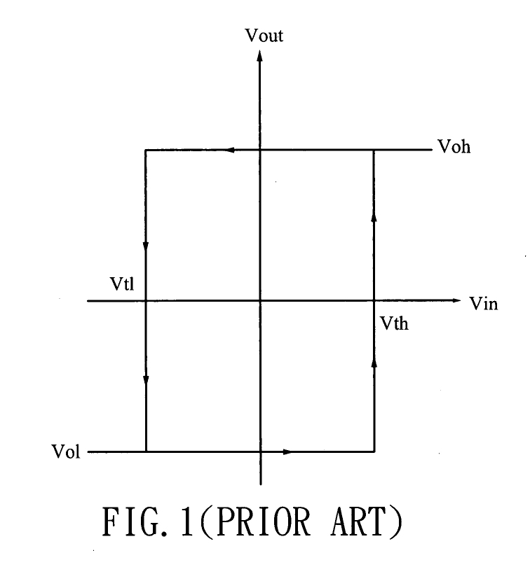

FIG. 2A is a schematic view of the hysteresis circuit according to the prior art;

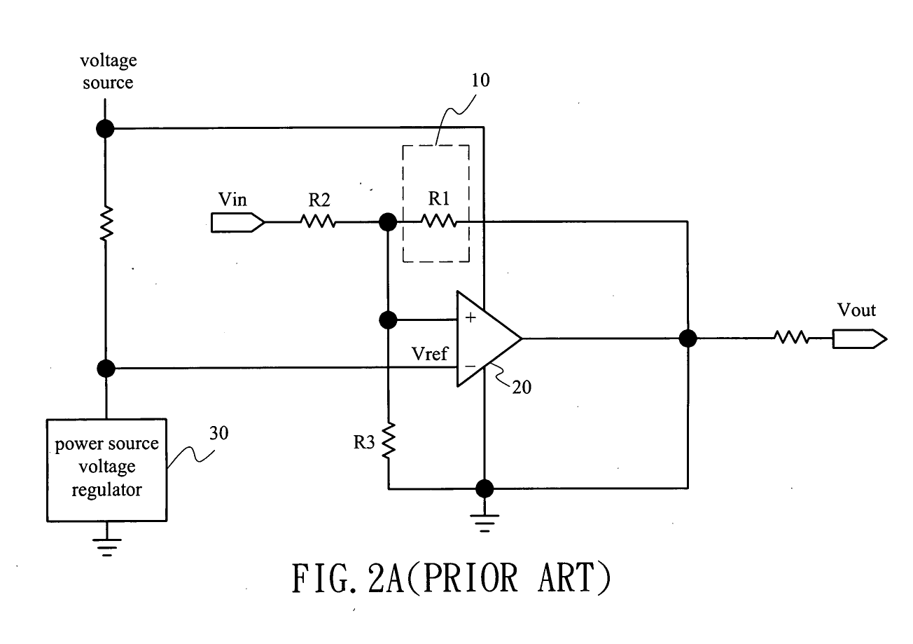

FIG. 2B is a schematic view of another hysteresis circuit according to the prior art;

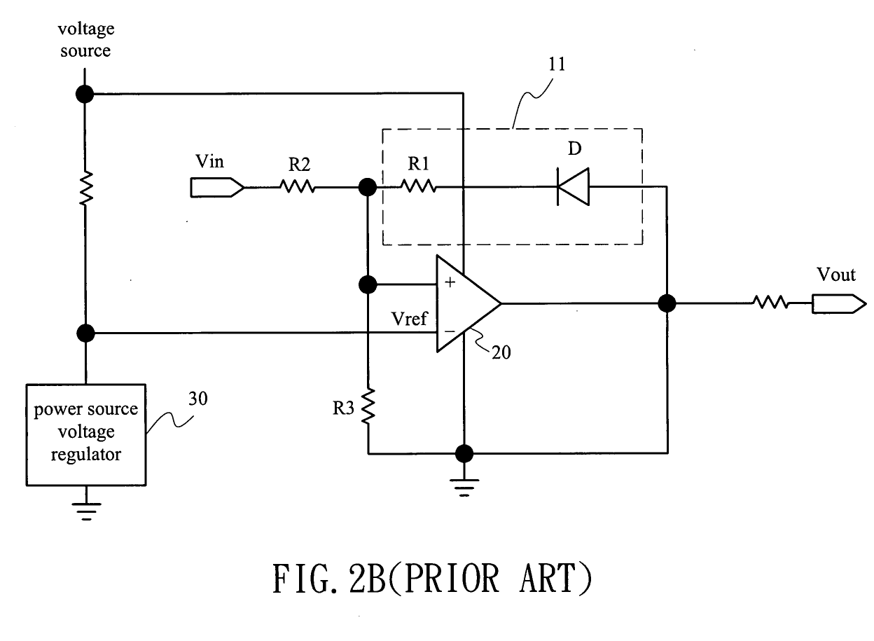

FIG. 3 is a schematic view of the hysteresis circuit according to an embodiment of the present invention; and

FIG. 4 is a schematic view of the amplifier circuit according to an embodiment of the present invention.

### DETAILED DESCRIPTION OF THE INVENTION

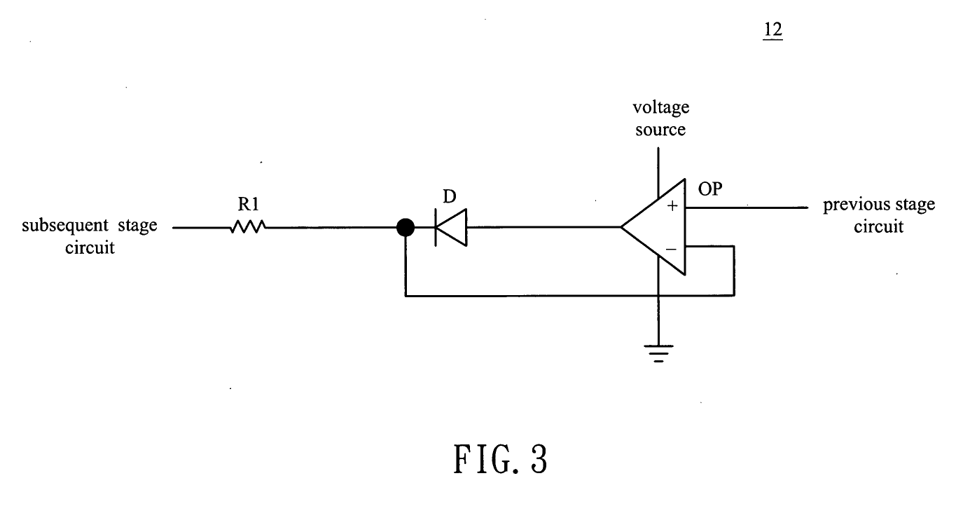

Referring to FIG. 3, a schematic view of the hysteresis circuit according to an embodiment of the present invention is shown. As shown in FIG. 3, the hysteresis circuit 12 of the present invention includes a first resistor R1, a diode D, and an operational amplifier OP. The illustration of the connecting relationship of each circuit element is given as follows.

The first resistor R1 has a first end and a second end, the first end of the first resistor R1 is electrically coupled to a subsequent stage circuit, and the second end of the first resistor R1 is electrically coupled to an output end of the diode D.

The diode D has an input end (i.e. a positive end) and an output end (i.e. a negative end), the input end of the diode D is electrically coupled to an output end of the operational amplifier OP, and the output end of the diode D is electrically coupled between the second end of the first resistor R1 and a second input end of the operational amplifier OP.

The operational amplifier OP has a first input end (i.e. a positive phase input end), a second input end (i.e. a negative phase input end), and an output end. The first input end of the operational amplifier OP is electrically coupled to a previous stage circuit, the second input end of the operational amplifier OP is electrically coupled to the output end of the diode D, and the output end of the operational amplifier OP is electrically coupled to the input end of the diode D.

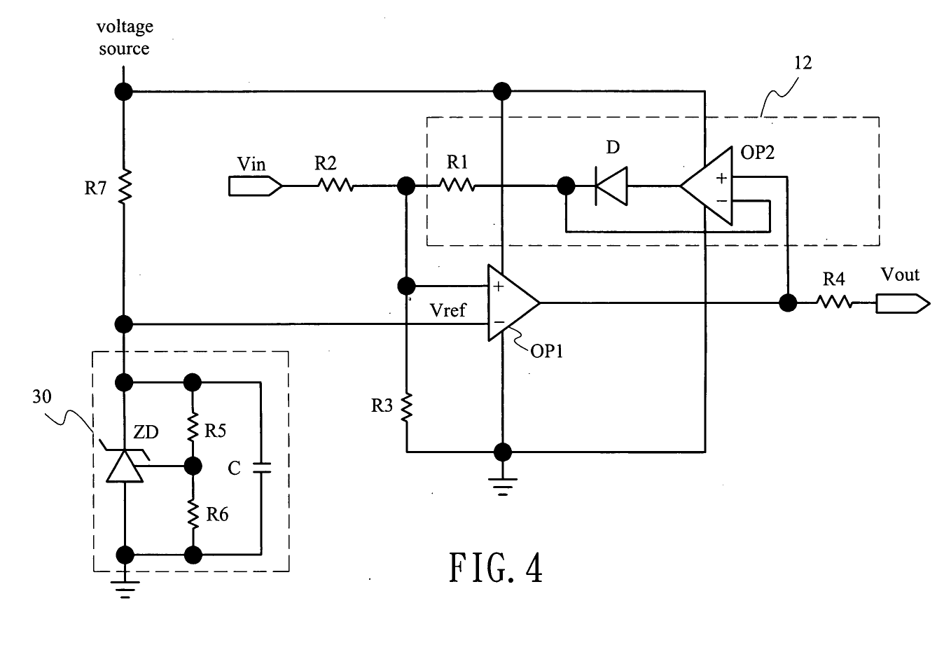

Next, referring to FIG. 4, a schematic view of the amplifier circuit according to the embodiment of the present invention is shown. As shown in FIG. 4, the amplifier circuit of the present invention includes a first operational amplifier OP1 and a hysteresis circuit 12. The illustration of the connecting relation of each circuit element is given as follows.

The first operational amplifier OP1 has a first input end (i.e. a positive phase input end), a second input end (i.e. a negative phase input end), and an output end. The first input end of the first operational amplifier OP1 is electrically coupled to the first end of the first resistor R1, a second end of a second resistor R2, and a first end of a third resistor R3. The second input end of the first operational amplifier OP1 is electrically coupled to the power source voltage regulator 30, and receives the reference voltage signal Vref output by the power source voltage regulator 30. The output end of the first operational amplifier OP1 is electrically coupled to the first input end of a second operational amplifier OP2 and a first end of a fourth resistor R4.

A first end of the second resistor R2 receives an input voltage signal Vin, a second end of the third resistor R3 is electrically coupled to a ground end, and a second end of the fourth resistor R4 provides an output voltage signal Vout. The second operational amplifier OP2 has a first input end (i.e. a positive phase input end), a second input end (i.e. a negative phase input end), and an output end. The first input end of the second operational amplifier OP2 is electrically coupled to the output end of the first operational amplifier OP1 and the first end of the fourth resistor R4. The second input end of the second operational amplifier OP2 is electrically coupled to the output end of the diode D. The output end of the second operational amplifier OP2 is electrically coupled to the input end of the diode D. The output end of the diode D is electrically coupled to the second end of the first resistor R1 and the second input end of the second operational amplifier OP2.

The power source voltage regulator 30 includes a Zener diode ZD, a fifth resistor R5, a sixth resistor R6, and a capacitor C.

Firstly, a first end of the capacitor C is electrically coupled to a first end of the fifth resistor R5, and a second end of the capacitor C is electrically coupled to a second end of the sixth resistor R6. The first end of the fifth resistor R5 is electrically coupled to a first end (i.e. a negative end) of the Zener diode ZD, the second input end of the first operational OP1, and a second end of a seventh resistor R7. A second end of the fifth resistor R5 is electrically coupled to a third end of the Zener diode ZD and a first end of the sixth resistor R6. A second end of the sixth resistor R6 is electrically coupled to a second end (i.e. a positive end) of the Zener diode ZD and the ground end. The capacitor C, the fifth resistor R5, and the sixth resistor R6 form a parallel loop, and the fifth resistor R5, the sixth resistor R6, and the Zener diode ZD form a parallel loop.

The circuit operation principle is illustrated as follows.

When the first input end of the first operational amplifier OP1 receives the input voltage signal Vin, the first operational amplifier OP1 compares the input voltage signal Vin and the reference voltage signal Vref. When the input voltage signal Vin is larger than the reference voltage signal Vref, the output end of the first operational amplifier OP1 outputs the high level voltage signal Voh. After the high level voltage signal Voh is input to the first input end of the first operational amplifier OP1 through the feedback path formed by the second operational amplifier OP2, the diode D, and the first resistor R1, the difference value between the input voltage signal Vin and the reference voltage signal Vref input to the first operational amplifier OP1 is increased. In this manner, the output of the first operational amplifier OP1 is not interfered by the noise to generate misoperation.

Similarly, when the input voltage signal Vin is less than the reference voltage signal Vref, the output end of the first operational amplifier OP1 outputs the low level voltage signal Vol. After the low level voltage signal Vol is input to the first input end of the first operational amplifier OP1 through the feedback path formed by the second operational amplifier OP2, the diode D, and the first resistor R1, the difference value between the input voltage signal Vin and the reference voltage signal Vref input to the first operational amplifier OP1 is increased. In this manner, the output of the first operational amplifier OP1 is not interfered by the noise to generate misoperation.

The second operational amplifier OP2 and the diode in the hysteresis circuit 12 form a super diode circuit, so the forward voltage drop of the diode D is nearly zero. Therefore, the hysteresis circuit 12 may not affect the feedback voltage signal input to the first operational amplifier OP1.

To sum up, the hysteresis circuit applied to the comparator and the amplifier circuit thereof according to the present invention mainly can solve the problem that the hysteresis circuit formed by the positive feedback resistor and the diode affects the feedback voltage signal, such that the hysteresis ranges of the comparator is more precise.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A hysteresis circuit applied to a comparator, the comparator having a first input end, a second input end and an output end, the first input end receiving an input voltage signal, the second input end receiving a reference voltage signal, the comparator outputting a high level voltage signal or a lower level voltage signal from the output end according to a difference of the input voltage signal and the reference voltage signal, the hysteresis circuit comprising:
a first resistor, electrically coupled between the first input end and the output end of the comparator;
a diode, electrically coupled to the first resistor; and
an operational amplifier, having a first input end, a second input end and an output end, electrically coupled between the diode and the output end of the comparator, the first input end of the operational amplifier receiving the high level voltage signal or the low level voltage signal, and the output end of the operational amplifier outputting the high level voltage signal or the low level voltage signal, so as to increase the difference between the input voltage signal and the reference voltage signal of the comparator.

2. The hysteresis circuit applied to a comparator as claimed in claim 1, wherein the operational amplifier and the diode form a super diode circuit, such that forward voltage drop of the diode is nearly zero.

3. The hysteresis circuit applied to a comparator as claimed in claim 1, wherein the diode has an input end and an output end, the input end of the diode is electrically coupled to the output end of the operational amplifier, and the output end of the diode is electrically coupled to the first resistor and the second input end of the operational amplifier.

4. The hysteresis circuit applied to a comparator as claimed in claim 1, wherein when the input voltage signal is larger than the reference voltage signal, the output end of the comparator outputs the high level voltage signal.

5. The hysteresis circuit applied to a comparator as claimed in claim 1, wherein when the input voltage signal is lower than the reference voltage signal, the output end of the comparator outputs the low level voltage signal.

6. An amplifier circuit, comprising:
a first operational amplifier, having a first input end, a second input end and an output end, the first input end receiving an input voltage signal, the second input end receiving a reference voltage signal, the first operational amplifier outputting a high level voltage signal or a low level voltage signal from the output end according to a difference between the input voltage signal and the reference voltage signal; and
a hysteresis circuit, electrically coupled between the first input end and the output end of the first operational amplifier, wherein the hysteresis circuit comprises:
a first resistor, electrically coupled between the first input end and the output end of the first operational amplifier;
a diode, electrically coupled to the first resistor; and
a second operational amplifier, having a first input end, a second input end and an output end, electrically coupled between the diode and the output end of the first operational amplifier, the first input end of the second operational amplifier receiving the high level voltage signal or the low level voltage signal, and the output end of the second operational amplifier outputting the high level voltage signal or the low level voltage signal, so as to increase the difference between the input voltage signal and the reference voltage signal of the first operational amplifier.

7. The amplifier circuit as claimed in claim 6, wherein the second operational amplifier and the diode form a super diode circuit, such that forward voltage drop of the diode is nearly zero.

8. The amplifier circuit as claimed in claim 6, wherein the diode has an input end and an output end, the input end of the diode is electrically coupled to the output end of the second operational amplifier, and the output end of the diode is electrically coupled to the first resistor and the second input end of the second operational amplifier.

9. The amplifier circuit as claimed in claim 6, wherein when the input voltage signal is larger than the reference voltage signal, the output end of the first operational amplifier outputs the high level voltage signal.

10. The amplifier circuit as claimed in claim 6, wherein when the input voltage signal is lower than the reference voltage signal, the output end of the first operational amplifier outputs the low level voltage signal.
